(19) United States
(12) Patent Application Publication
(10) Pub. No.: US 2025/0379416 A1
(43) Pub. Date: Dec. 11, 2025

(54) LASER PACKAGE DEVICE AND MANUFACTURING METHOD THEREFOR AND LASER LIGHT SOURCE DEVICE

(71) Applicant: Wistron Corporation, New Taipei City (TW)

(72) Inventors: Huang-Yu LIN, New Taipei City (TW); Hung-Chun PAN, New Taipei City (TW); Hao-Chun HSIEH, New Taipei City (TW)

(21) Appl. No.: 18/813,184

(22) Filed: Aug. 23, 2024

(30) Foreign Application Priority Data
Jun. 7, 2024 (TW) 113121379

(51) Int. Cl. H01S 5/02345; H01S 5/02208; H01S 5/02251; H01S 5/02253; H01S 5/0239; H01S 5/042; H01S 5/068; H01S 5/0683

(52) U.S. Cl. CPC H01S 5/02345; H01S 5/02208; H01S 5/02251; H01S 5/02253; H01S 5/0239; H01S 5/0421; H01S 5/06804; H01S 5/0683

(57) ABSTRACT

A laser package device and a manufacturing method therefor and a laser light source device are provided. The laser package device includes a substrate, a laser diode, a thermal detector, and a cover. In the laser package device, the substrate includes a first conductive layer, and the laser diode and the thermal detector are located on the substrate and are electrically connected to the first conductive layer. The cover covers the laser diode and the thermal detector. The cover includes a stepped groove. The stepped groove is configured to accommodate the laser diode and the thermal detector. In the disclosure, a heat dissipation effect of the laser package device is effectively improved by using the cover.

### CROSS-REFERENCE TO RELATED APPLICATION

This non-provisional application claims priority under 35 U.S.C. § 119 (a) to patent application Ser. No. 11/312,1379 filed in Taiwan, R.O.C. on Jun. 7, 2024, the entire contents of which are hereby incorporated by reference.

### BACKGROUND

### Technical Field

The disclosure relates to an optical laser technology, and in particular, to a laser package device and a manufacturing method therefor and a laser light source device using the laser package device.

### Related Art

With the high development of an optical communication speed, a laser diode with advantages of a high speed and a small size is increasingly widely applied. Compared with a general laser diode, the laser diode that can be used in a high-speed optical communication product has a higher power, and therefore generates more heat, impeding driving of the laser diode. Therefore, a cover is arranged on outside of a single laser diode, to assist in heat dissipation of the laser diode. However, in addition to the laser diode, passive elements such as a thermal detector and a light detector are still arranged on a circuit board. Although the above cover can cover the single laser diode, the cover cannot cover the elements with different heights arranged densely.

### SUMMARY

The disclosure provides a laser package device. The laser package device includes a substrate, a laser diode, a thermal detector, and a cover. The substrate includes a first conductive layer. The laser diode is located on the substrate and is electrically connected to the first conductive layer. The thermal detector is located on the substrate and is electrically connected to the first conductive layer. The cover covers the laser diode and the thermal detector. The cover includes a stepped groove. The stepped groove is configured to accommodate the laser diode and the thermal detector.

In an embodiment, the stepped groove includes a first groove configured to accommodate the laser diode and a second groove configured to accommodate the thermal detector, and a step difference exists between the first groove and the second groove.

In an embodiment, the laser package device further includes a plurality of first conductive bumps and a plurality of second conductive bumps. The first conductive bumps are located on the laser diode and are electrically connected to the laser diode. The second conductive bumps are located on the thermal detector and are electrically connected to the thermal detector. In addition, the cover further includes a first conductive assembly and a second conductive assembly. The first conductive assembly penetrates the cover, is located in the first groove, and is bonded to the first conductive bumps, so that the laser diode located in the first groove is electrically connected to the first conductive assembly through the first conductive bumps. The second conductive assembly penetrates the cover, is located in the second groove, and is bonded to the second conductive bumps, so that the thermal detector located in the second groove is electrically connected to the second conductive assembly through the second conductive bumps.

In an embodiment, the first conductive assembly includes a second conductive layer, a third conductive layer, and a first conductive pillar. The second conductive layer is located in the first groove and is bonded to the first conductive bumps. The third conductive layer is located on an outer surface of the cover, and corresponds to the second conductive layer. The first conductive pillar penetrates the cover and is connected to the second conductive layer and the third conductive layer.

In an embodiment, the second conductive assembly includes a fourth conductive layer, a fifth conductive layer, and a second conductive pillar. The fourth conductive layer is located in the second groove, and is bonded to the second conductive bumps. The fifth conductive layer is located on the outer surface of the cover and corresponds to the fourth conductive layer. The second conductive pillar penetrates the cover, and is connected to the fourth conductive layer and the fifth conductive layer.

In an embodiment, the first conductive layer serves as a shared N-type electrode of the laser diode and the thermal detector, the third conductive layer serves as a first P-type electrode of the laser diode, and the fifth conductive layer serves as a second P-type electrode of the thermal detector.

In an embodiment, when a plurality of laser diodes are arranged, the laser diodes are located side by side on the substrate and located in the first groove. The laser diodes are jointly electrically connected to the first conductive layer and are electrically connected to the second conductive layer respectively through the first conductive bumps.

In an embodiment, when a plurality of thermal detectors are arranged, the thermal detectors are located side by side on the substrate and located in the second groove. The thermal detectors are jointly electrically connected to the first conductive layer and are electrically connected to the fourth conductive layer respectively through the second conductive bumps.

In an embodiment, the laser package device further includes a light detector located on the substrate, and the thermal detector is located between the laser diode and the light detector and is arranged in a staggered manner.

In an embodiment, the laser package device further includes a plurality of third conductive bumps and a plurality of fourth conductive bumps located on the light detector and electrically connected to the light detector. The cover further covers the light detector, so that the second groove accommodates the light detector. The cover further includes a third conductive assembly and a fourth conductive assembly. The third conductive assembly penetrates the cover and is located in the second groove, so as to be bonded to the third conductive bumps, so that the light detector is electrically connected to the third conductive assembly through the third conductive bumps. The fourth conductive assembly penetrates the cover and is located in the second groove, so as to be bonded to the fourth conductive bumps, so that the light detector is electrically connected to the fourth conductive assembly through the fourth conductive bumps.

In an embodiment, the third conductive assembly includes a sixth conductive layer, a seventh conductive layer, and a third conductive pillar. The sixth conductive layer is located in the second groove and is bonded to the third conductive bumps. The seventh conductive layer is located on an outer surface of the cover and corresponds to the sixth conductive layer. The third conductive pillar penetrates the cover and is connected to the sixth conductive layer and the seventh conductive layer. The fourth conductive assembly includes an eighth conductive layer, a ninth conductive layer, and a fourth conductive pillar. The eighth conductive layer is located in the second groove and is bonded to the fourth conductive bumps. The ninth conductive layer is located on the outer surface of the cover and corresponds to the eighth conductive layer. The fourth conductive pillar penetrates the cover and is connected to the eighth conductive layer and the ninth conductive layer, to use the seventh conductive layer and the ninth conductive layer as external electrodes of the light detector.

In an embodiment, the laser diode is selected from at least one of a distributed feedback (DFB) laser diode, an electro-absorption modulated laser (EML) diode, a Fabry-Perot laser (FP) laser diode, a distributed Bragg reflector (DBR), and a quantum dot (QD) laser diode.

The disclosure further provides a laser light source device. The laser light source device includes an optical fiber array, a lens, and a laser package device. The lens is adjacent to the optical fiber array. The laser package device is adjacent to the lens, and forms a light path with the lens and the optical fiber array. The laser package device includes a substrate, a laser diode, a thermal detector, and a cover. The substrate includes a first conductive layer. The laser diode is located on the substrate and is electrically connected to the first conductive layer. The thermal detector is located on the substrate and is electrically connected to the first conductive layer. The cover is located on the substrate and covers the laser diode and the thermal detector. The cover includes a stepped groove. The stepped groove is configured to accommodate the laser diode and the thermal detector.

In an embodiment, the laser light source device further includes a connector, a circuit board, and a housing. The connector is connected to the optical fiber array. The circuit board has the laser package device arranged thereon, and the laser diode and the thermal detector are electrically connected to the circuit board. The housing covers the optical fiber array, the lens, the laser package device, the circuit board, and the connector, and exposes a part of the connector.

In an embodiment, the optical fiber array and the lens are located on the substrate.

The disclosure further provides a manufacturing method for a laser package device. The method includes: mounting a laser diode to a substrate; mounting a thermal detector and a light detector to the substrate, so that the thermal detector is located between the laser diode and the light detector and is arranged in a staggered manner, where the laser diode and the thermal detector are respectively provided with a plurality of first conductive bumps and a plurality of second conductive bumps; and mounting a cover to the substrate, to cover the laser diode and the thermal detector. The cover includes a stepped groove, a first conductive assembly, and a second conductive assembly. The stepped groove includes a first groove configured to accommodate the laser diode and a second groove configured to accommodate the thermal detector. A step difference exists between the first groove and the second groove. The first conductive assembly penetrates the cover, is located in the first groove, and is bonded to the first conductive bumps, and the second conductive assembly penetrates the cover, is located in the second groove, and is bonded to the second conductive bumps, to finish a laser package device.

### BRIEF DESCRIPTION OF THE DRAWINGS

FIG. 1 is a schematic structural diagram of a laser package device according to an embodiment of the disclosure.

FIG. 2 is a schematic structural exploded view of the laser package device according to an embodiment of the disclosure.

FIG. 3 is a schematic diagram of the laser package device from a rear perspective according to an embodiment of the disclosure.

FIG. 4 is a schematic diagram of the laser package device from a front perspective according to an embodiment of the disclosure.

FIG. 5 is a schematic sectional diagram of the laser package device according to an embodiment of the disclosure.

FIG. 6 is a schematic diagram of an internal structure of a cover according to an embodiment of the disclosure.

FIG. 7 is a schematic diagram of locations of chips in a laser package device according to an embodiment of the disclosure.

FIG. 8 shows simulated surface temperature curves of a laser package device with a cover and a laser package device without a cover according to an embodiment of the disclosure.

FIG. 9 is a schematic flowchart of manufacturing a laser package device according to an embodiment of the disclosure.

FIG. 10A to FIG. 10E are schematic structural diagrams of steps of manufacturing a laser package device according to an embodiment of the disclosure.

FIG. 11A is a schematic diagram of mounting a cover in front of a substrate according to an embodiment of the disclosure.

FIG. 11B is a schematic diagram of mounting a cover behind a substrate according

to an embodiment of the disclosure.

FIG. 12 is a schematic sectional diagram of a laser package device according to another embodiment of the disclosure.

FIG. 13 is a schematic structural diagram of a laser light source device according to an embodiment of the disclosure.

FIG. 14 is a schematic structural diagram of a laser light source device mounted in a housing according to an embodiment of the disclosure.

FIG. 15 is a schematic diagram of a laser light source device applied to a switch according to an embodiment of the disclosure.

### DETAILED DESCRIPTION

Preferred embodiments are provided below for detailed description. However, the embodiments are merely used as examples for illustration, and do not limit the protection scope of the disclosure. In addition, some elements are omitted in the drawings in the embodiments, to clearly show the technical features of the disclosure. Same reference numerals in all of the drawings indicate same or similar elements.

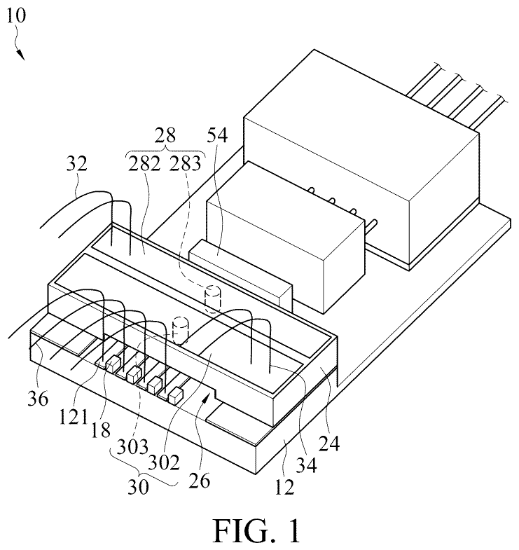

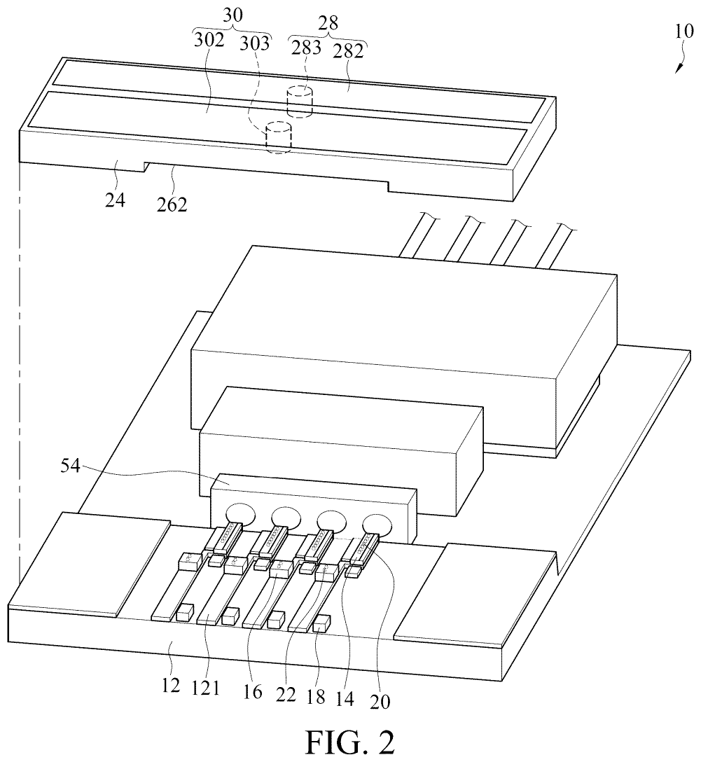

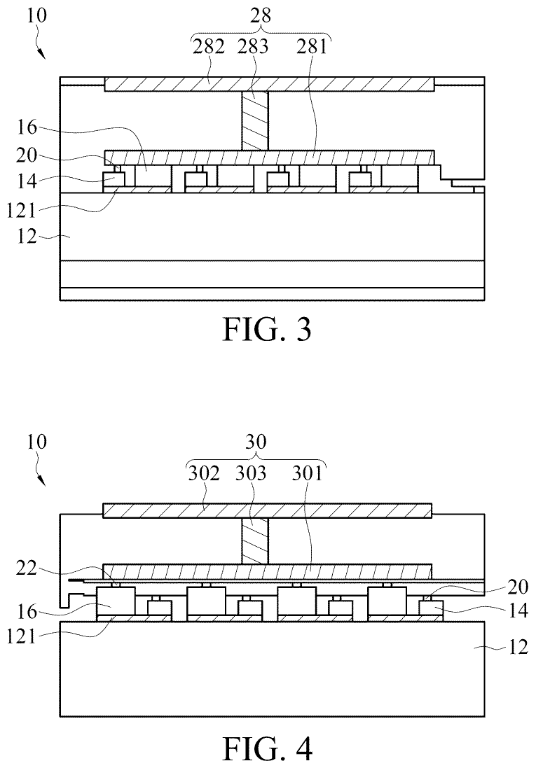

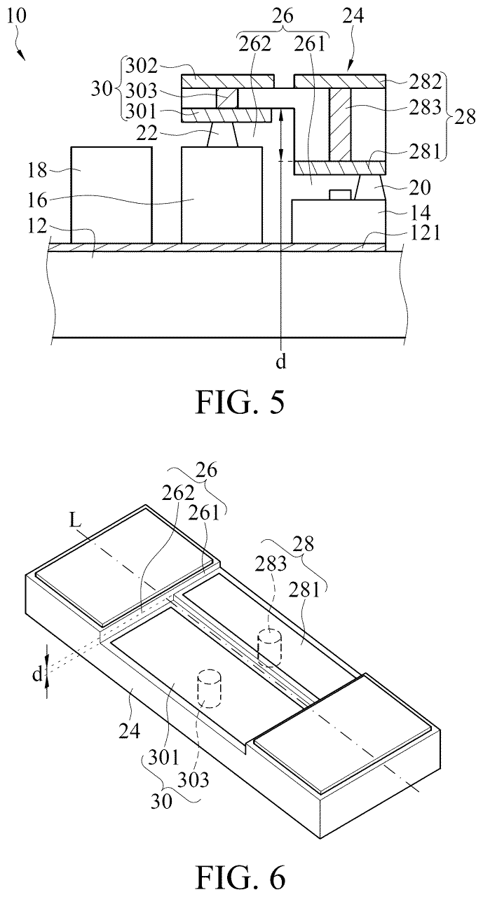

FIG. 1 is a schematic structural diagram of a laser package device according to an embodiment of the disclosure. FIG. 2 is a schematic structural exploded view of the laser package device according to an embodiment of the disclosure. FIG. 3 is a schematic diagram of the laser package device from a rear perspective according to an embodiment of the disclosure. FIG. 4 is a schematic diagram of the laser package device from a front perspective according to an embodiment of the disclosure. FIG. 5 is a schematic sectional diagram of the laser package device according to an embodiment of the disclosure. Referring to FIG. 1 to FIG. 5 together, a laser package device 10 includes a substrate 12, a laser diode 14, a thermal detector 16, a light detector 18, a plurality of first conductive bumps 20, a plurality of second conductive bumps 22, and a cover 24. In this embodiment of the disclosure, four laser diodes 14, four thermal detectors 16, and four light detectors 18 are used as an example, but the disclosure is not limited to the quantities.

As shown in FIG. 1 to FIG. 5, in the laser package device 10, the substrate 12 is made of a ceramic heat dissipation material, and the substrate 12 includes a first conductive layer 121. The first conductive layer 121 is a patterned metal layer formed on a surface of the substrate 12. The laser diodes 14 are located side by side on the substrate 12 and are jointly electrically connected to the first conductive layer 121. The thermal detectors 16 are located side by side on the substrate 12 and are close to the laser diodes 14. The thermal detectors 16 are jointly electrically connected to the first conductive layer 121, and each thermal detector 16 corresponds to a laser diode 14, to detect a temperature of the laser diode 14 through the thermal detector 16. The light detectors 18 are also located on the substrate 12. The thermal detectors 16 are located between the laser diodes 14 and the light detectors 18 and are arranged in a staggered manner, to avoid a failure of receiving light monitoring intensity on back surfaces of the laser diodes 14 by the light detectors 18 as a result of blocking of the thermal detectors 16 between the light detectors 18 and the laser diodes 14. The first conductive bumps 20 are located on the laser diode 14 and are electrically connected to the laser diode 14. The second conductive bumps 22 are located on the thermal detector 16 and are electrically connected to the thermal detector 16. The cover 24 is located on the substrate 12 and covers the laser diode 14 and the thermal detector 16. Referring to FIG. 6, the cover 24 includes a stepped groove 26, a first conductive assembly 28, and a second conductive assembly 30. The stepped groove 26 includes a first groove 261 and a second groove 262. Since the laser diode 14 and the thermal detector 16 have different heights, the first groove 261 is a shallow groove configured to accommodate the laser diode 14, the second groove 262 is a deep groove configured to accommodate the thermal detector 16, and a step difference d exists between the first groove 261 and the second groove 262. The first conductive assembly 28 penetrates the cover 24 and is located in the first groove 261, so as to be bonded to the first conductive bumps 20, so that the laser diode 14 located in the first groove 261 is electrically connected to the first conductive assembly 28 through the first conductive bumps 20. The second conductive assembly 30 penetrates the cover 24 and is located in the second groove 262, so as to be bonded to the second conductive bumps 22, so that the thermal detector 16 located in the second groove 262 is electrically connected to the second conductive assembly 30 through the second conductive bumps 22.

In an embodiment, the first conductive assembly 28 includes a second conductive layer 281, a third conductive layer 282, and a first conductive pillar 283. The second conductive layer 281 is located in the first groove 261 and is connected to the first conductive bumps 20 of each laser diode 14, the third conductive layer 282 is located on an outer surface of the cover 24 and corresponds to the second conductive layer 281, and the first conductive pillar 283 penetrates the cover 24 and is connected to the second conductive layer 281 and the third conductive layer 282, to conduct a current from the laser diode 14 to the third conductive layer 282 at a top of the cover 24 through the first conductive bumps 20, the second conductive layer 281, and the first conductive pillar 283. The second conductive assembly 30 includes a fourth conductive layer 301, a fifth conductive layer 302, and a second conductive pillar 303. The fourth conductive layer 301 is located in the second groove 262 and is bonded to the second conductive bumps 22 of each thermal detector 16, the fifth conductive layer 302 is located on the outer surface of the cover 24 and corresponds to the fourth conductive layer 301, and the second conductive pillar 303 penetrates the cover 24 and is connected to the fourth conductive layer 301 and the fifth conductive layer 302, to conduct a current from the thermal detector 16 to the fifth conductive layer 302 at the top of the cover 24 through the second conductive bumps 22, the fourth conductive layer 301, and the second conductive pillar 303. Positions and quantities of first conductive pillars 283 and second conductive pillars 303 may be adjusted correspondingly based on different needs, but the disclosure is not limited to the above embodiment. In this embodiment, the first conductive layer 121 serves as a shared N-type electrode of the laser diode 14 and the thermal detector 16, the third conductive layer 282 serves as a first P-type electrode of all of the laser diodes 14, and the fifth conductive layer 302 serves as a second P-type electrode of all of the thermal detectors 16. Moreover, adjacent laser diodes 14 and adjacent thermal detectors 16 are respectively connected in parallel to each other, which can achieve an optimal circuit configuration, to reduce a risk of short circuits.

In an embodiment, the laser diode 14 and the thermal detector 16 have different heights. For example, the height of the laser diode 14 is 0.1 mm, and the height of the thermal detector 16 is 0.2 mm. In this case, a depth of the first groove 261 in the cover 24 is 0.1 mm, to accommodate the laser diode 14, and a depth of the second groove 262 is 0.2 mm, to accommodate the thermal detector 16. In an embodiment, the cover 24 is integrally formed by joining and sintering ceramic materials.

In the disclosure, laser arrays and components in the laser package device 10 in the disclosure are relatively dense. A four channel array (four laser diodes 14, four thermal detectors 16, and four light detectors 18) is used as an example herein. Through the design of the cover 24, the laser diode 14 can be directly connected from the third conductive layer 282 on the cover 24 to an external circuit through only two wires 32, and the thermal detector 16 can be directly connected from the fifth conductive layer 302 to the external circuit through only two wires 34. Together with original four wires 36 of the light detector 18, a total of only 8 wires, namely, the wires 32, the wires 34, and the wires 36 are needed. Based on the above, in the disclosure, originally required 24 wires are reduced to 8 wires. Therefore, a quantity of wires is reduced, and a production process is accelerated.

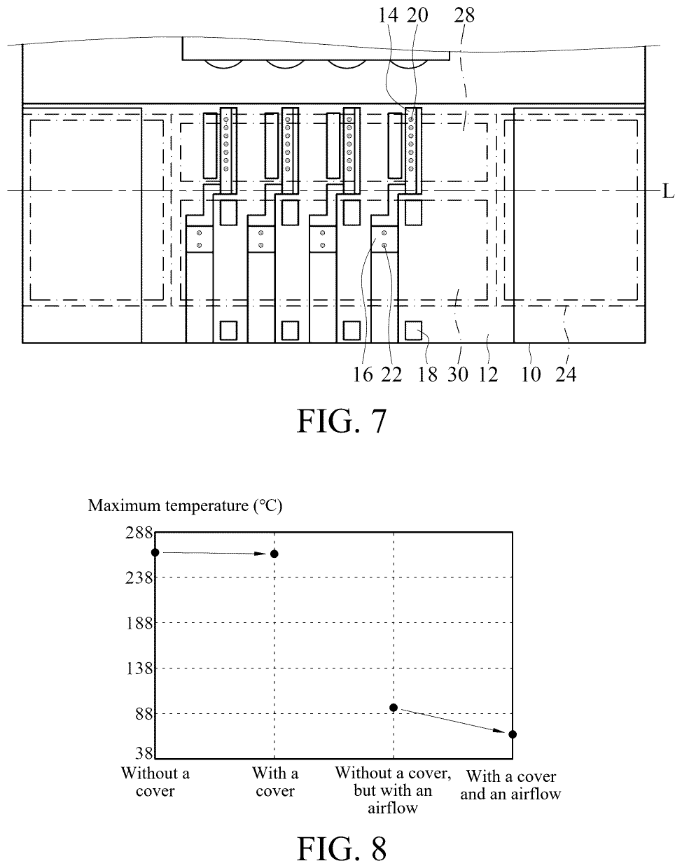

Referring to FIG. 2, FIG. 6, and FIG. 7 together, the cover 24 is mounted to the substrate 12 through side walls on two sides, and covers and is in contact with the laser diode 14 and the thermal detector 16. In a horizontal direction (a direction X), the laser diodes 14 arranged in a one-dimensional array share an electrode (share the first conductive assembly 28), and the thermal detectors 16 arranged in a one-dimensional array share an electrode (share the second conductive assembly 30). Therefore, an allowable error is extremely large. In a vertical direction (a direction Y), if a step difference line L between the first groove 261 and the second groove 262 in the cover 24 is used as a reference line, during translation in the vertical direction, short circuits caused by a loop formed by the first conductive assembly 28 at a top of the laser diode 14 and the second conductive assembly 30 at a top of the thermal detector 16 needs to be avoided. Therefore, an allowable error range in the vertical direction may reach a high error in a range of +0.5 mm to −0.44 mm.

In an embodiment, the laser diode 14 is selected from at least one of a distributed feedback (DFB) laser diode, an electro-absorption modulated laser (EML) diode, a Fabry-Perot laser (FP) laser diode, a distributed Bragg reflector (DBR), and a quantum dot (QD) laser diode. In other words, the laser diode 14 may include one or two, or even any combination of more than two.

In the disclosure, through the design of the structure of the cover 24 in the laser package device 10, thermal resistance can be effectively reduced, thereby improving a heat dissipation effect of the whole package structure. In detail, in the disclosure, two heat dissipation paths can be respectively formed at two opposite ends of the laser diode 14 through the substrate 12 and the cover 24, to form a circuit similar to a parallel circuit having a relatively low overall resistance. Compared with an existing laser package device without a cover, the laser package device 10 has characteristics of a lower overall resistance and generating lower heat energy. A thermal effect simulation is performed on the laser package device 10 designed with the cover 24 shown in FIG. 1 and a laser package device designed with no cover. As shown in FIG. 8, after implementation of the simulation, the laser package device 10 with the cover 24 has a temperature about 0.2° C. lower than that of the laser package device without a cover. When an airflow is supplied to enhance convection, the temperature of the laser package device 10 with the cover 24 supplied with the airflow decreases by 31.9% compared to the laser package device without a cover supplied with the airflow, proving a heat dissipation effect of the cover 24. Based on the above, a cooling effect can be achieved for the laser package device 10 through the heat dissipation effect of the cover 24. In this way, a power and energy required by a thermoelectric cooling chip for cooling the laser package device 10 can be reduced. Moreover, since temperature rise causes reduction of a laser output power, an input power needs to be compensated to satisfy a standard output power for use. The cooling can further reduce a to-be-compensated laser input power.

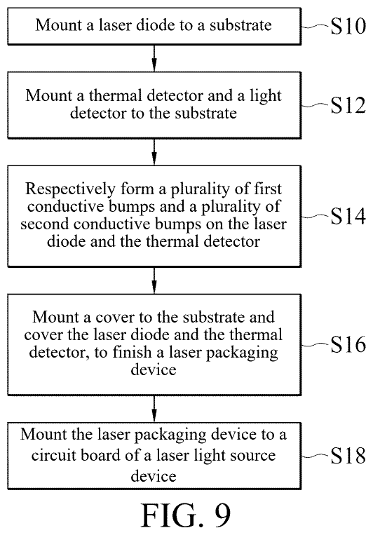

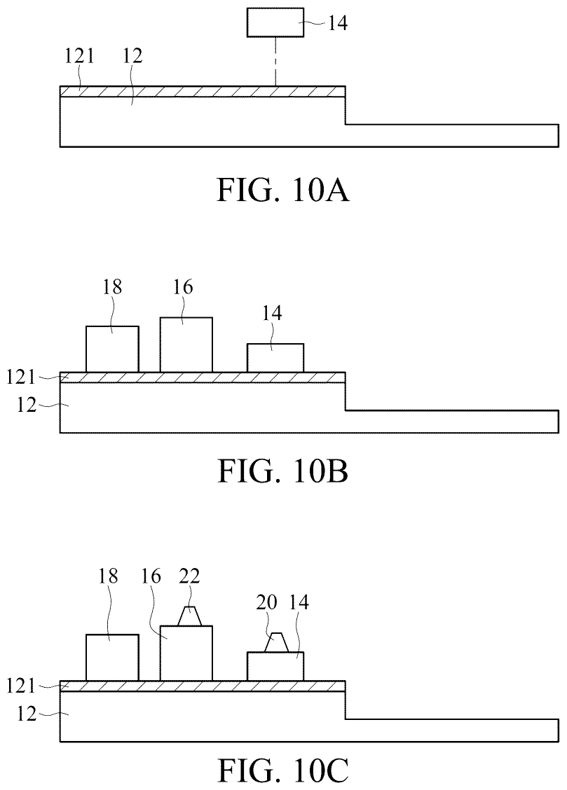

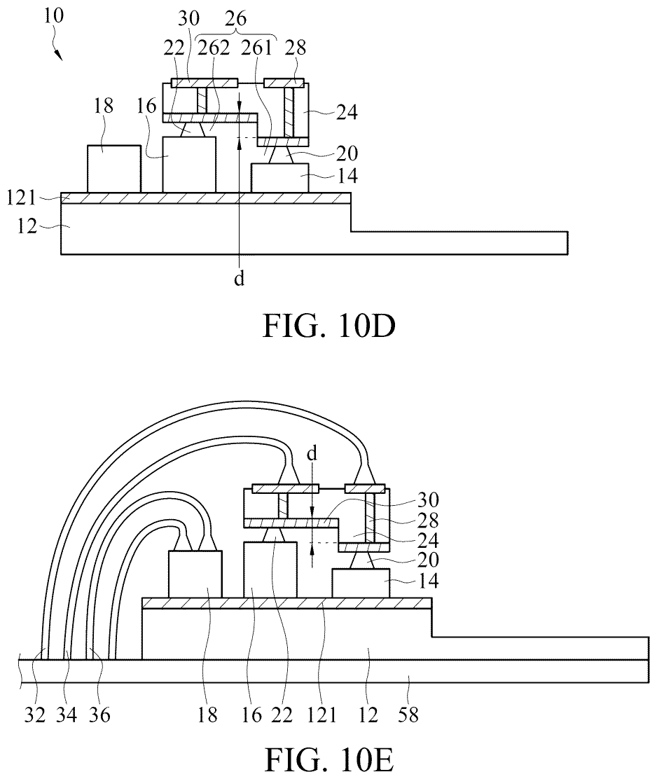

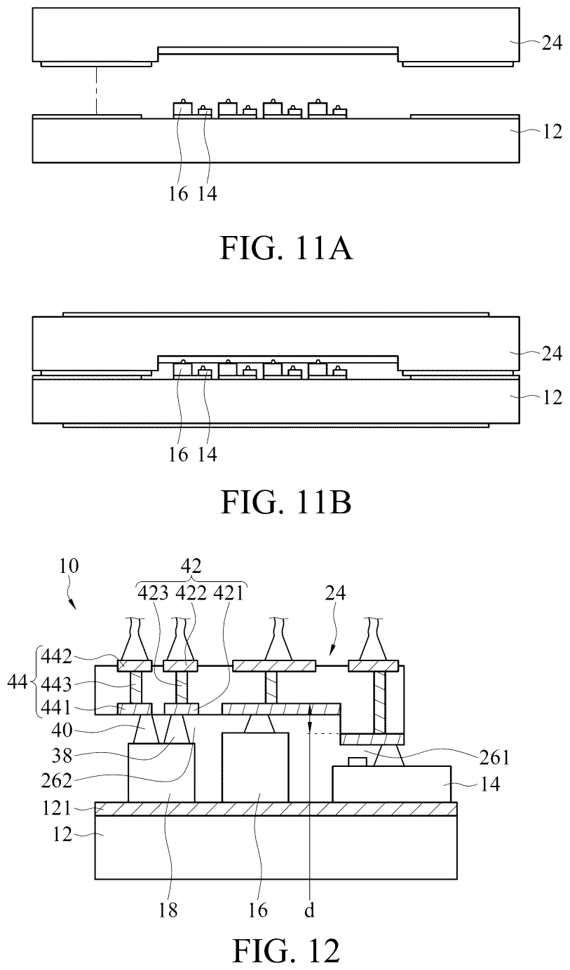

FIG. 9 is a schematic flowchart of manufacturing a laser package device according to an embodiment of the disclosure. FIG. 10A to FIG. 10E are schematic structural diagrams of steps of manufacturing a laser package device according to an embodiment of the disclosure. Refer to FIG. 9 and FIG. 10A to FIG. 10E together. First, as shown in step S10 and FIG. 10A, a laser diode 14 is picked up and placed on the first conductive layer 121 of the substrate 12, and die bonding is performed under a eutectic bonding condition, to mount the laser diode 14 to the substrate 12. As shown in step S12 and FIG. 10B, a thermal detector 16 and a light detector 18 are picked up and placed on the first conductive layer 121 of the substrate 12, and are adhered to the substrate 12 with a conductive adhesive. The conductive adhesive may be but is not limited to a silver adhesive, to mount the thermal detector 16 and light detector 18 to the substrate 12, so that the thermal detector 16 is located between the laser diode 14 and the light detector 18 and is arranged in a staggered manner. As shown in step S14 and FIG. 10C, wire bonding is performed on the laser diode 14 and the thermal detector 16, and the wire is cut off, to respectively form the plurality of first conductive bumps 20 and the plurality of second conductive bumps 22 on the laser diode 14 and the thermal detector 16. As shown in step S16 and FIG. 10D, referring to FIG. 11A and FIG. 11B together, the cover 24 is welded to the substrate 12 in a temperature condition of hot pressing and eutectic bonding, to mount the cover 24 to the substrate 12 and cover the laser diode 14 and the thermal detector 16, so that the first conductive assembly 28 of the cover 24 is bonded to the first conductive bumps 20 and the second conductive assembly 30 is bonded to the second conductive bumps 22, thereby finishing a laser package device 10. A detailed structure of the cover 24 is the same as that in the above embodiment. Therefore, for the detailed structure, reference may be made to the above description, and the details are not described herein again. Furthermore, after the manufacturing of the laser package device 10 is completed, the laser package device 10 may be further mounted to a circuit board 58 of a laser light source device. As shown in step S18 and FIG. 10E, the plurality of wires 32, 34, and 36 respectively electrically connect the first conductive assembly 28 (the third conductive layer 282), the second conductive assembly 30 (the fifth conductive layer 302), and the light detector 18 to the circuit board 58 by using the wire bonding technology, so that the laser diode 14 is electrically connected to the circuit board 58 through the first conductive bumps 20, the first conductive assembly 28, and the wires 32, the thermal detector 16 is electrically connected to the circuit board 58 through the second conductive bumps 22, the second conductive assembly 30, and the wires 34, and the light detector 18 is electrically connected to the circuit board 58 through the wires 36.

In the above manufacturing process, in the disclosure, after the step of mounting the thermal detector 16 and the light detector 18 to the substrate 12, the first conductive bumps 20 and the second conductive bumps 22 are respectively formed on the laser diode 14 and the thermal detector 16. In another embodiment, in the disclosure, before the laser diode 14, the thermal detector 16, and the light detector 18 are mounted to the substrate 12, the first conductive bumps 20 and the second conductive bumps 22 are already respectively formed on the laser diode 14 and thermal detector 16. Therefore, after the laser diode 14, the thermal detector 16, and the light detector 18 are mounted to the substrate 12, the cover 24 may be directly mounted.

In an embodiment, as shown in FIG. 12, in the laser package device 10, the cover 24 can further cover the light detector 18. The laser package device 10 further includes a plurality of third conductive bumps 38 and a plurality of fourth conductive bumps 40. The third conductive bumps 38 and the fourth conductive bumps 40 are located on the light detector 18 and electrically connected to the light detector 18. Since the cover 24 further covers the light detector 18, the second groove 262 in the cover 24 accommodates the light detector 18. The cover 24 further includes a third conductive assembly 42 and a fourth conductive assembly 44. The third conductive assembly 42 penetrates the cover 24 and is located in the second groove 262, so as to be bonded to the third conductive bumps 38, so that the light detector 18 located in the second groove 262 is electrically connected to the third conductive assembly 42 through the third conductive bumps 38. The fourth conductive assembly 44 penetrates the cover 24 and is located in the second groove 262, so as to be bonded to the fourth conductive bumps 40, so that the light detector 18 is electrically connected to the fourth conductive assembly 44 through the fourth conductive bumps 40. Other structures are the same as those in the above embodiment. Therefore, details are not described herein again.

In an embodiment, the third conductive assembly 42 includes a sixth conductive layer 421, a seventh conductive layer 422, and a third conductive pillar 423. The sixth conductive layer 421 is located in the second groove 262 and is connected to the third conductive bumps 38 of each light detector 18, the seventh conductive layer 422 is located on the outer surface of the cover 24 and corresponds to the sixth conductive layer 421, and the third conductive pillar 423 penetrates the cover 24 and is connected to the sixth conductive layer 421 and the seventh conductive layer 422, to conduct a current from the light detector 18 to the seventh conductive layer 422 at the top of the cover 24 through the third conductive bumps 38, the sixth conductive layer 421, and the third conductive pillar 423. The fourth conductive assembly 44 includes an eighth conductive layer 441, a ninth conductive layer 442, and a fourth conductive pillar 443. The eighth conductive layer 441 is located in the second groove 262 and is bonded to the fourth conductive bumps 40 of each light detector 18, the ninth conductive layer 442 is located on the outer surface of the cover 24 and corresponds to the eighth conductive layer 441, and the fourth conductive pillar 443 penetrates the cover 24 and is connected to the eighth conductive layer 441 and the ninth conductive layer 442, to conduct a current from the light detector 18 to the ninth conductive layer 442 at the top of the cover 24 through the fourth conductive bumps 40, the eighth conductive layer 441, and the fourth conductive pillar 443, so as to use the seventh conductive layer 422 and the ninth conductive layer 442 as external electrodes of the light detector 18.

In an embodiment, the first conductive layer 121, the second conductive layer 281, the third conductive layer 282, the fourth conductive layer 301, the fifth conductive layer 302, the sixth conductive layer 421, the seventh conductive layer 422, the eighth conductive layer 441, and the ninth conductive layer 442 may be made of various conductive materials, such as gold, tin, or gold tin alloys, but the disclosure is not limited thereto. In an embodiment, the first conductive pillar 283, the second conductive pillar 303, the third conductive pillar 423, and the fourth conductive pillar 443 are vias filled with metal or alloy materials, such as tungsten. Although the first conductive pillar 283, the second conductive pillar 303, the third conductive pillar 423, and the fourth conductive pillar 443 are made of metal or alloy materials, the disclosure is not limited thereto.

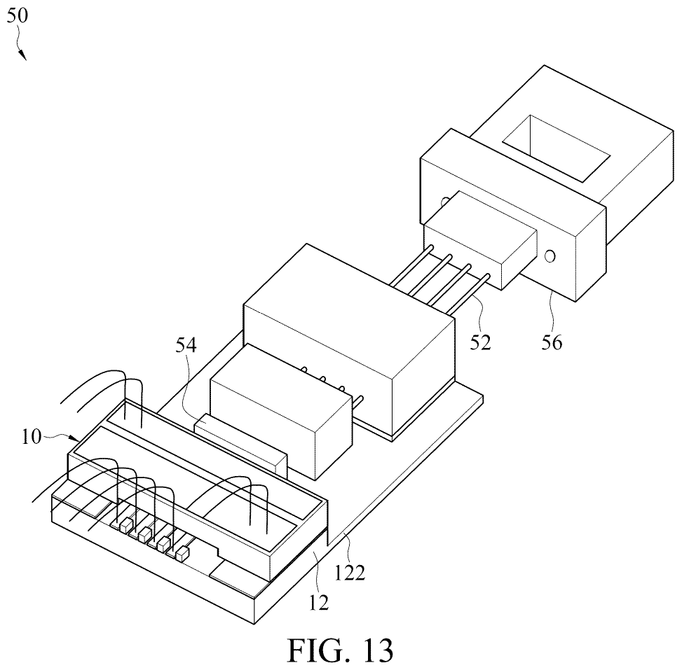

FIG. 13 is a schematic structural diagram of a laser light source device according to an embodiment of the disclosure. As shown in FIG. 13, a laser light source device 50 includes an optical fiber array 52, a lens 54, and a laser package device 10. A substrate 12 of the laser package device 10 is an L-shaped substrate. In other words, a side of the substrate 12 includes a thin plate portion 122. The lens 54 and the optical fiber array 52 are arranged on the thin plate portion 122. The lens 54 is adjacent to the optical fiber array 52, and the laser package device 10 is adjacent to the lens 54, so that the laser package device 10, the lens 54, and the optical fiber array 52 forms a light path. A detailed structure of the laser package device 10 is the same as that in the above embodiments. For the detailed structure, refer to the above description, and the details are not described herein again.

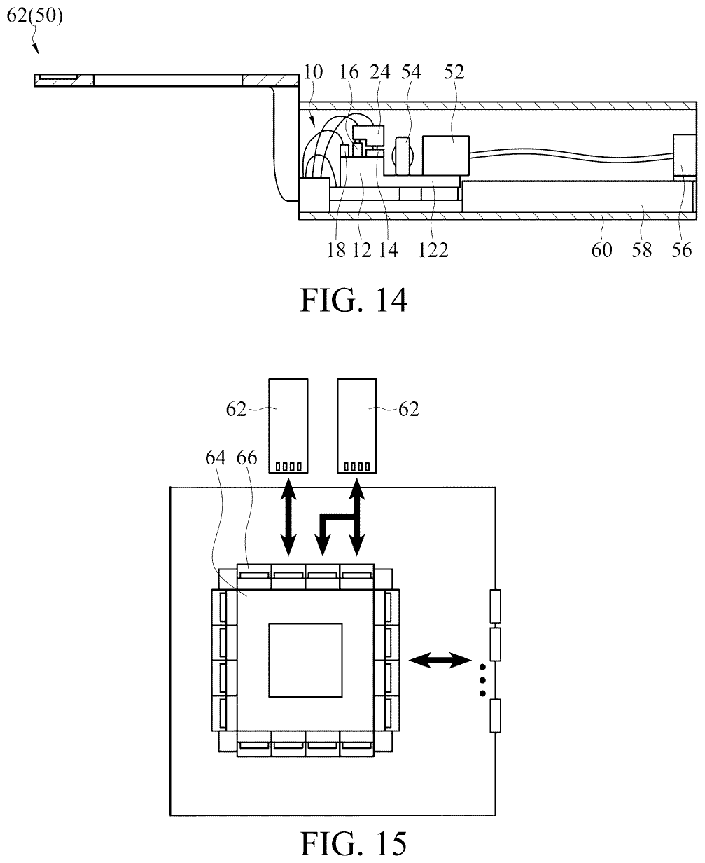

FIG. 14 is a schematic structural diagram of a laser light source device mounted in a housing according to an embodiment of the disclosure. Referring to both FIG. 13 and FIG. 14, the laser light source device 50 further includes a connector 56, a circuit board 58, and a housing 60. The connector 56 is connected to the optical fiber array 52, the circuit board 58 has the laser package device 10 mounted thereto and the lens 54 and the optical fiber array 52 mounted to the substrate 12 thereof, and the laser diode 14, the thermal detector 16, and the light detector 18 are electrically connected to the circuit board 58. The housing 60 covers the optical fiber array 52, the lens 54, the laser package device 10, the connector 56, and the circuit board 58, and exposes a part of the connector 56, to finish a plug-in laser light source device 62, for example, an external laser small form-factor pluggable (ELSFP) module. The plug-in laser light source device 62 may serve as a co-package optics (CPO) light source or a silicon photon (SiPh) light source.

In an embodiment, the laser light source device of the disclosure may be applied to a schematic diagram of a switch with a CPO module. As shown in FIG. 14 and FIG. 15, the switch 64 includes a plurality of CPO modules 66. The plug-in laser light source device 62 is usually arranged at a pluggable position at a rear end of the switch 64, so that the plug-in laser light source device 62 can serve as a light source configured to be driven by the CPO modules 66. A general CPO module 66 uses a plurality of channels for driving. When a plug-in laser light source device 62 needs to correspond to at least one set of CPO modules 66, a plurality of channels need to be implemented to reduce space and costs. Therefore, a laser package device 10 is designed with a plurality of arrays of chips such as laser diodes 14 and modules in a same space. The laser package device 10 of the disclosure can achieve desirable matching by virtue of heat dissipation design and component configuration of the cover 24.

In summary, in the disclosure, the stepped groove of the cover is arranged above the laser diode and the thermal detector, to effectively improve a heat dissipation effect of the whole package structure. Furthermore, in the disclosure, through the stepped groove of the cover and the conductive bumps, the cover covers the laser diode and thermal detector and forms an electrical connection, to prevent damage to components or lasers after assembly. In addition, the cover not only facilitates heat dissipation, but also can further cover the laser diodes and the thermal detectors with different heights arranged densely, and have advantages of reducing a quantity of wires and reducing manufacturing time.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A laser package device, comprising:
a substrate, comprising a first conductive layer;
a laser diode, located on the substrate and electrically connected to the first conductive layer;
a thermal detector, located on the substrate and electrically connected to the first conductive layer; and
a cover, covering the laser diode and the thermal detector and comprising a stepped groove, wherein the stepped groove is configured to accommodate the laser diode and the thermal detector.

2. The laser package device according to claim 1, wherein the stepped groove comprises a first groove configured to accommodate the laser diode and a second groove configured to accommodate the thermal detector, and a step difference exists between the first groove and the second groove.

3. The laser package device according to claim 2, further comprising: a plurality of first conductive bumps, located on the laser diode and electrically connected to the laser diode; and a plurality of second conductive bumps, located on the thermal detector and electrically connected to the thermal detector, wherein the cover further comprises a first conductive assembly and a second conductive assembly, the first conductive assembly penetrates the cover, is located in the first groove, and is bonded to the first conductive bumps, so that the laser diode located in the first groove is electrically connected to the first conductive assembly through the first conductive bumps, and the second conductive assembly penetrates the cover, is located in the second groove, and is bonded to the second conductive bumps, so that the thermal detector located in the second groove is electrically connected to the second conductive assembly through the second conductive bumps.

4. The laser package device according to claim 3, wherein the first conductive assembly comprises: a second conductive layer, located in the first groove and bonded to the first conductive bumps; a third conductive layer, located on an outer surface of the cover and corresponding to the second conductive layer; and a first conductive pillar, penetrating the cover and connected to the second conductive layer and the third conductive layer.

5. The laser package device according to claim 4, wherein the second conductive assembly comprises: a fourth conductive layer, located in the second groove and bonded to the second conductive bumps; a fifth conductive layer, located on the outer surface of the cover and corresponding to the fourth conductive layer; and a second conductive pillar, penetrating the cover and connected to the fourth conductive layer and the fifth conductive layer.

6. The laser package device according to claim 5, wherein the first conductive layer serves as a shared N-type electrode of the laser diode and the thermal detector, the third conductive layer serves as a first P-type electrode of the laser diode, and the fifth conductive layer serves as a second P-type electrode of the thermal detector.

7. The laser package device according to claim 5, wherein when a plurality of laser diodes are arranged, the laser diodes are located side by side on the substrate and located in the first groove, and the laser diodes are jointly electrically connected to the first conductive layer and are electrically connected to the second conductive layer respectively through the first conductive bumps.

8. The laser package device according to claim 5, wherein when a plurality of thermal detectors are arranged, the thermal detectors are located side by side on the substrate and located in the second groove, and the thermal detectors are jointly electrically connected to the first conductive layer and are electrically connected to the fourth conductive layer respectively through the second conductive bumps.

9. The laser package device according to claim 2, further comprising a light detector located on the substrate, wherein the thermal detector is located between the laser diode and the light detector and is arranged in a staggered manner.

10. The laser package device according to claim 9, further comprising a plurality of third conductive bumps and a plurality of fourth conductive bumps located on the light detector and electrically connected to the light detector, wherein the cover further covers the light detector, so that the second groove accommodates the light detector, the cover further comprises a third conductive assembly and a fourth conductive assembly, the third conductive assembly penetrates the cover and is located in the second groove, so as to be bonded to the third conductive bumps, so that the light detector is electrically connected to the third conductive assembly through the third conductive bumps, and the fourth conductive assembly penetrates the cover and is located in the second groove, so as to be bonded to the fourth conductive bumps, so that the light detector is electrically connected to the fourth conductive assembly through the fourth conductive bumps.

11. The laser package device according to claim 10, wherein the third conductive assembly comprises: a sixth conductive layer, located in the second groove and bonded to the third conductive bumps; a seventh conductive layer, located on an outer surface of the cover and corresponding to the sixth conductive layer; and a third conductive pillar, penetrating the cover and connected to the sixth conductive layer and the seventh conductive layer; and the fourth conductive assembly comprises: an eighth conductive layer, located in the second groove and bonded to the fourth conductive bumps; a ninth conductive layer, located on the outer surface of the cover and corresponding to the eighth conductive layer; and a fourth conductive pillar, penetrating the cover and connected to the eighth conductive layer and the ninth conductive layer, to use the seventh conductive layer and the ninth conductive layer as external electrodes of the light detector.

12. The laser package device according to claim 1, wherein the laser diode is selected from at least one of a distributed feedback (DFB) laser diode, an electro-absorption modulated laser (EML) diode, a Fabry-Perot laser (FP) laser diode, a distributed Bragg reflector (DBR), and a quantum dot (QD) laser diode.

13. A laser light source device, comprising:
an optical fiber array;
a lens, adjacent to the optical fiber array; and
a laser package device, adjacent to the lens, forming a light path with the lens and the optical fiber array, and comprising:
a substrate, comprising a first conductive layer;
a laser diode, located on the substrate and electrically connected to the first conductive layer;
a thermal detector, located on the substrate and electrically connected to the first conductive layer; and
a cover, covering the laser diode and the thermal detector and comprising a stepped groove, wherein the stepped groove is configured to accommodate the laser diode and the thermal detector.

14. The laser light source device according to claim 13, wherein the stepped groove comprises a first groove configured to accommodate the laser diode and a second groove configured to accommodate the thermal detector, and a step difference exists between the first groove and the second groove.

15. The laser light source device according to claim 14, wherein the laser package device further comprises: a plurality of first conductive bumps, located on the laser diode and electrically connected to the laser diode; and a plurality of second conductive bumps, located on the thermal detector and electrically connected to the thermal detector; and the cover further comprises a first conductive assembly and a second conductive assembly, wherein the first conductive assembly penetrates the cover, is located in the first groove, and is bonded to with the first conductive bumps, so that the laser diode located in the first groove is electrically connected to the first conductive assembly through the first conductive bumps, and the second conductive assembly penetrates the cover, is located in the second groove, and is bonded to the second conductive bumps, so that the thermal detector located in the second groove is electrically connected to the second conductive assembly through the second conductive bumps.

16. The laser light source device according to claim 15, further comprising: a connector, connected to the optical fiber array; a circuit board, having the laser package device arranged thereon, wherein the laser diode and the thermal detector are electrically connected to the circuit board; and a housing, covering the optical fiber array, the lens, the laser package device, the circuit board, and the connector, and exposing a part of the connector.

17. The laser light source device according to claim 16, wherein the optical fiber array and the lens are located on the substrate.

18. The laser light source device according to claim 14, further comprising a light detector located on the substrate, wherein the thermal detector is located between the laser diode and the light detector and is arranged in a staggered manner.

19. The laser light source device according to claim 18, further comprising a plurality of third conductive bumps and a plurality of fourth conductive bumps located on the light detector and electrically connected to the light detector, wherein the cover further covers the light detector, so that the second groove accommodates the light detector, the cover further comprises a third conductive assembly and a fourth conductive assembly, the third conductive assembly penetrates the cover and is located in the second groove, so as to be bonded to the third conductive bumps, so that the light detector is electrically connected to the third conductive assembly through the third conductive bumps, and the fourth conductive assembly penetrates the cover and is located in the second groove, so as to be bonded to the fourth conductive bumps, so that the light detector is electrically connected to the fourth conductive assembly through the fourth conductive bumps.

20. A manufacturing method for a laser package device, comprising:
mounting a laser diode to a substrate;
mounting a thermal detector and a light detector to the substrate, so that the thermal detector is located between the laser diode and the light detector and is arranged in a staggered manner, wherein the laser diode and the thermal detector are respectively provided with a plurality of first conductive bumps and a plurality of second conductive bumps; and
mounting a cover to the substrate to cover the laser diode and the thermal detector, wherein the cover comprises a stepped groove, a first conductive assembly, and a second conductive assembly, the stepped groove comprises a first groove configured to accommodate the laser diode and a second groove configured to accommodate the thermal detector, a step difference exists between the first groove and the second groove, the first conductive assembly penetrates the cover, is located in the first groove, and is bonded to the first conductive bumps, and the second conductive assembly penetrates the cover, is located in the second groove, and is bonded to the second conductive bumps, to finish a laser package device.

21. The manufacturing method for a laser package device according to claim 20, wherein after the step of mounting the thermal detector and the light detector to the substrate, the method further comprises: respectively forming the first conductive bumps and the second conductive bumps on the laser diode and the thermal detector; and further mounting the laser package device to a circuit board of a laser light source device, and electrically connecting the first conductive bumps and the second conductive bumps to the circuit board by using a plurality of wires, so that the laser diode is electrically connected to the circuit board through the first conductive bumps and the wires and the thermal detector is electrically connected to the circuit board through the second conductive bumps and the wires.
